(19) United States
(12) Patent Application Publication
(10) Pub. No.: US 2025/0197430 A1
(43) Pub. Date: Jun. 19, 2025

(54) CYCLIC TITANIUM OXIDE NANOCLUSTER COMPOSITION AND DEVICE WITH SAME

(71) Applicant: City University of Hong Kong, Kowloon (HK)

(72) Inventors: Alex Kwan Yue Jen, Kowloon (HK); Fengzhu Li, Kowloon (HK); Chaowei Zhao, Kowloon (HK)

(21) Appl. No.: 18/543,653

(22) Filed: Dec. 18, 2023

(51) Int. Cl. C07F 7/28; B82Y 30/00; H10K 50/16; H10K 71/12; H10K 85/30; H10K 85/50

(52) U.S. Cl. CPC C07F 7/28; B82Y 30/00; H10K 50/16; H10K 71/12; H10K 85/341; H10K 85/50

(57) ABSTRACT

A cyclic titanium-oxide cluster (CTOC)-based composition of Formula Ti₃₂O₁₆(OCH₂CH₂O)₃₂(R1COO)ₓ(ArCOO)₁₆₋ₓ(R2O)₁₆ (Formula I).

### TECHNICAL FIELD

The present disclosure relates to a series of cyclic Ti-oxo cluster (CTOC) compositions and their uses, such as in organic-inorganic hybrid perovskite solar cells with improved stability and optoelectronic performance.

### BACKGROUND OF THE INVENTION

Various nanomaterials, such as metal oxide nanoparticles, metal-organic nanosheets, graphene or graphene oxide, etc. have been employed as functional layers in perovskite solar cells (PVSCs) to increase the power conversion efficiency (PCE) and improve the device durability. These functional layers cannot only passivate defects of the perovskite layer but also endow strong interfacial communication between the perovskite material and charge transport layer, resulting in reduced charge recombination and enhanced charge extraction and transport. Moreover, some functional layers can effectively avoid oxygen and water penetration to perovskite material and mitigate diffusion of ions (such as X⁻, Pb²⁺), enabling significant protection from both environment attacks and inherent phase degradation. Meanwhile, the general concern about harmful Pb leakage of PVSCs can also be resolved by using those layers with excellent Pb capturing capability. However, most of these nanomaterials suffer from issues such as complicated synthesis, severe storage requirements, limited fabrication conditions, lack of detailed structure information, uneven composition distribution, and low reproducibility, and so on. Therefore, developing new nanomaterials with clear structures, high yield, good reproducibility, and especially, high tailoring flexibility to comprise as many functional groups as possible in one material, remains highly desirable.

A nanocluster is a kind of nanomaterial with not only similar or identical composition and structure in the core to the corresponding bulk material phase, but also well-defined isolated molecular character. For example, following the attempts to produce downsized metal oxide nanoparticles, metal oxide nanoclusters can be obtained with varied metal and oxygen atom ratios and various protecting ligands or not. The inherent structure and composition correlation between the bulk metal oxide and corresponding metal-oxo nanoclusters can often afford their similar physiochemical properties, such as band gaps, energy levels, and work functions. Notably, metal-oxo clusters can usually be solution-processed into uniform films. Some representative metal-oxo clusters with specific variable surface ligands can endow their excellent structure modification opportunity for kinds of derivatization and functionalization.

As the molecular model of titanium oxide, much research attention has been paid to Ti-oxo clusters (TOCs) over the past several decades, and valuable detailed information on the hydrolysis and condensation of monomer Ti species into bulk TiO₂ has been obtained. Moreover, novel titanium oxide nanomaterials with atomically precise structures and tailorable functional groups can also be achieved. TOCs with both robust backbone structures and variable surface ligands can provide an excellent opportunity for this intended purpose. In this regard, a cyclic titanium oxide cluster (CTOC) with extreme stability towards the environment and common organic species has been developed to realize plenty of modifications on the cluster surface, thus enabling efficient and stable PVSCs with 25% efficiency and long-term stability under various conditions.

### SUMMARY OF THE INVENTION

Accordingly, the present invention discloses that CTOC be modified or derivatized with organic functional groups through different active sites on the CTOC.

According to a first aspect of the present invention, there is provided a cyclic titanium-oxide cluster (CTOC)-based composition of Formula I:

Ti₃₂O₁₆(OCH₂CH₂O)₃₂(R1COO)ₓ(ArCOO)₁₆₋ₓ(R2O)₁₆ (Formula I)
wherein:
x is an integer from 0 to 15,
R1 is selected from a group consisting of H—, CH₃—, CH₃CH₂—, CH₃CH₂CH₂—, (CH₃)₂CH—, (CH₃)₂CHCH₂—, (CH₃)₃C—, CH₂CH—, CH₂C(CH₃)—, CNCH₂—, CNCH₂CH₂—, HSCH₂—, HSCH₂CH₂—, NH₂CH₂—, NH₂CH₂CH₂—, OHCH₂—, OHCH₂CH₂—, CH₃NHCH₂— and (CH₃)₂NCH₂,
Ar is selected from a group consisting of o/m/p-CH₂CHPh—, o/m/p-CHCPh—, o/m/p-OHPh—, o/m/p-CH₃NHPh—, o/m/p-(CH₃)₂NPh—, o/m/p-SHPh—, o/m/p-CH₃SPh—, o/m/p-CH₃CH₂SPh—, o/m/p-F—Ph—, o/m/p-Cl—Ph—, o/m/p-Br—Ph—, o/m/p-I—Ph—, o/m/p-CF₃—Ph—, o/m/p-NH₂CH₂Ph—, o/m/p-(NH₃⁺X⁻)Ph—, o/m/p-(CH₃NH₂⁺X⁻)Ph—, o/m/p-[(CH₃)₃N⁺X⁻]Ph—, o/m/p-(NH₃⁺X⁻)CH₂Ph—, o/m/p-NH₂CH₂CH₂Ph— and o/m/p-(NH₃⁺X⁻)CH₂CH₂Ph—,

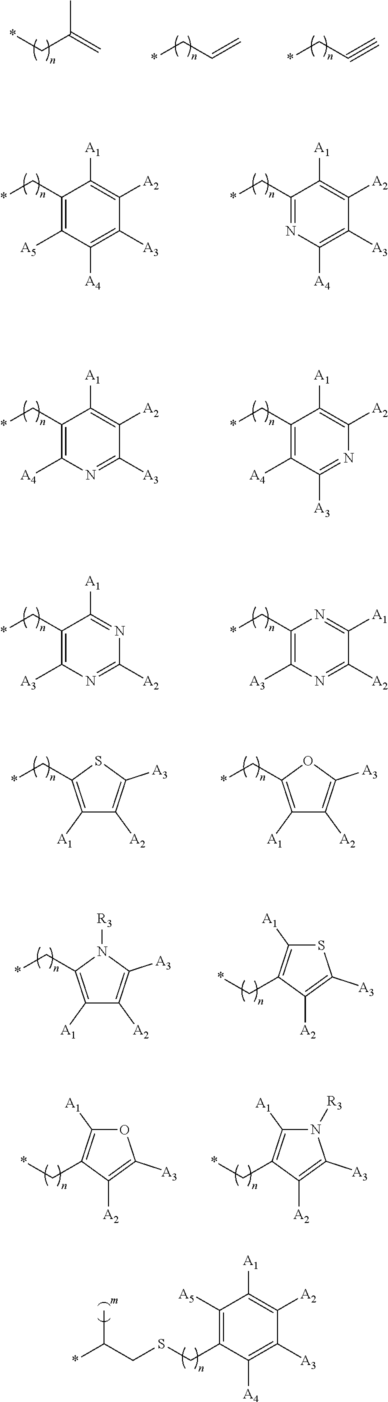

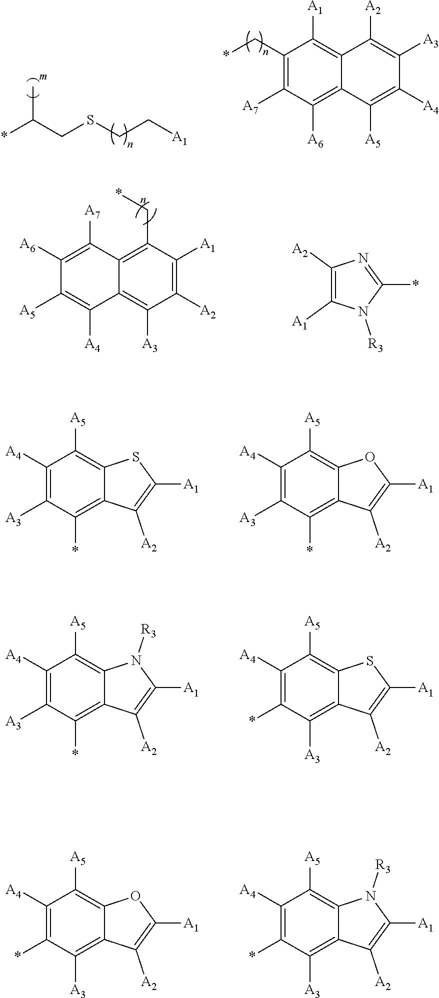

R2 is selected from a group consisting of CH₃—, CH₃CH₂—, CH₃CH₂CH₂—, (CH₃)₂CH—, CH₃CH₂CH₂CH₂—, OHCH₂CH₂—, OHCH₂CH₂CH₂—, SHCH₂CH₂—, SHCH₂CH₂CH₂—, NH₂CH₂CH₂—, NH₂CH₂CH₂CH₂—, CH₃NHCH₂CH₂—, (CH₃)₂NCH₂CH₂—, (NH₃⁺X⁻)CH₂CH₂—, (NH₃⁺X⁻)CH₂CH₂CH₂—, CH₃(NH₂⁺X⁻)CH₂CH₂—, (CH₃)₂(NH⁺X⁻)CH₂CH₂—,
X⁻ is selected from a group consisting of Cl⁻, Br⁻, I⁻, OTf⁻, BF₄⁻ and PF₆⁻,
each of A₁, A₂, A₃, A₄, A₅, A₆, A₇ is independently selected from a group consisting of: H, F, Cl, Br, I, CF₃,

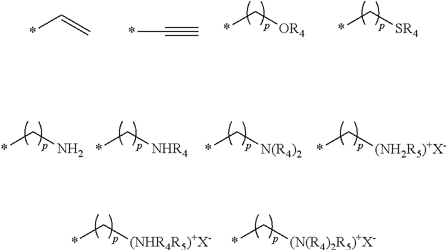

each of R₃, R₄, R₅ is independently selected from a group consisting of:

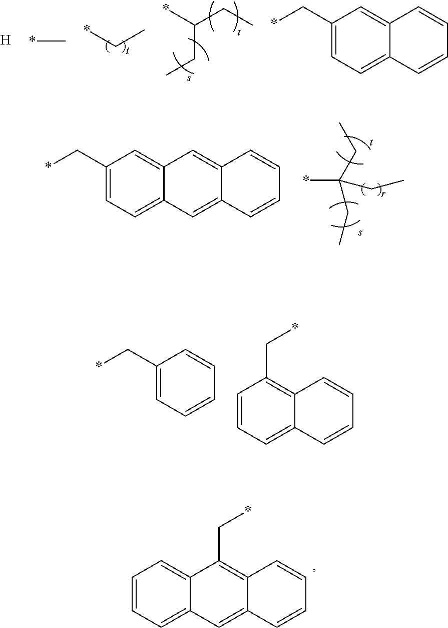

and
each of m, n, p, r, s and t is independently selected from an integer from 0 to 10.

In certain embodiments, the CTOC-based composition is of Formula II:

Ti₃₂O₁₆(OCH₂CH₂O)₃₂[(CH₃)₃CCOO]₈(C₆F₅COO)₈(CH₃CH₂O)₁₆ (Formula II)
(hereinafter called “CTOC-Ph-5F”).

In certain embodiments, the CTOC-based composition is of Formula III:

Ti₃₂O₁₆(OCH₂CH₂O)₃₂[(CH₃)₃CCOO]₈(p-CF₃PhCOO)₈(CH₃CH₂O)₁₆ (Formula III)
(hereinafter called “CTOC-Ph-CF3”).

In certain embodiments, the CTOC-based composition is of Formula IV:

Ti₃₂O₁₆(OCH₂CH₂O)₃₂[(CH₃)₃CCOO]₈(C₆H₄FCOO)₈(CH₃CH₂O)₁₆ (Formula IV)
(hereinafter called “CTOC-Ph-F”).

According to a second aspect of the present invention, there is provided a device including the cyclic titanium-oxide cluster (CTOC)-based composition of Formula I.

According to a third aspect of the present invention, there is provided a method of forming the device including the cyclic titanium-oxide cluster (CTOC)-based composition of Formula I, wherein said device includes a perovskite layer, and wherein a layer of the composition of Formula I is formed on said perovskite layer.

### BRIEF DESCRIPTION OF THE DRAWINGS

The foregoing aspects and many of the attendant advantages of this invention will become more readily appreciated as the same become better understood by reference to the following detailed description taken in conjunction with the accompanying drawings, wherein:

FIG. 1 depicts the general molecular structure of a tailorable CTOC-based nanocluster composition according to Formula I of the present invention;

FIG. 2a depicts the molecular structure of the CTOC-based nanocluster composition according to Formula II of the present invention (referred to as “CTOC-Ph-5F cluster”);

FIG. 2b depicts the molecular structure of the coordination mode of C6F5COO ligand to Ti of the CTOC-Ph-5F nanocluster composition of FIG. 2a;

FIG. 3a depicts the molecular structure of the CTOC-based nanocluster composition according to Formula III of the present invention (referred to as “CTOC-Ph-CF3 cluster”);

FIG. 3b depicts the molecular structure of the coordination mode of CF3PhCOO ligand to Ti of the CTOC-Ph-CF3 nanocluster composition of FIG. 3a;

FIG. 4a depicts the molecular structure of the CTOC-based nanocluster composition according to Formula IV of the present invention (referred to as “CTOC-Ph-F cluster”);

FIG. 4b depicts the molecular structure of the coordination mode of FPhCOO ligand to Ti of the CTOC-Ph-F nanocluster composition of FIG. 4a;

FIG. 5 shows a schematic view of a perovskite solar cell including the CTOC nanocluster composition according to the present invention;

FIG. 6 depicts the ¹H NMR spectrum of CTOC-Ph-5F nanocluster composition;

FIG. 7 depicts the ¹H NMR spectrum of CTOC-Ph-F nanocluster composition;

FIG. 8 depicts the UV-vis spectra of CTOC-Ph-F and CTOC-Ph-5F nanocluster compositions;

FIG. 9 depicts the TGA spectra of CTOC-Ph-F and CTOC-Ph-5F nanocluster compositions;

FIG. 10a depicts the EDX mapping of F and Ti of the perovskite films with the nanocluster composition according to the present invention;

FIG. 10b depicts the EDX mapping of F and Ti of the perovskite films without nanocluster composition clusters according to the present invention;

FIG. 11a depicts the high-resolution XPS spectra of Pb(4f) of perovskite film with and without nanocluster composition according to the present invention;

FIG. 11b depicts the high-resolution XPS spectra of I(3d) of perovskite film with and without nanocluster composition according to the present invention;

FIG. 12a depicts the steady-state PL spectrum of perovskite films with and without CTOC-Ph-5F nanocluster composition coating layer;

FIG. 12b depicts the time-resolved PL spectrum of perovskite films with and without CTOC-Ph-5F nanocluster composition coating layer;

FIG. 13a depicts the schematic illustration of the cluster interlayer in perovskite device with and without CTOC-Ph-5F nanocluster composition layer;

FIG. 13b depicts the J-V curves of champion devices with and without CTOC-Ph-5F nanocluster composition layer;

FIG. 14a depicts the XPS spectrum of Pb(4f) of fresh and aged perovskite films with and without CTOC-Ph-5F nanocluster composition;

FIG. 14b depicts the XPS spectrum of I(3d) of fresh and aged perovskite films with and without CTOC-Ph-5F nanocluster composition;

FIG. 15a depicts the respective solid fluorine-19 nuclear magnetic resonance (NMR ¹⁹F) spectrum of CTOC-Ph-5F and perovskite, CTOC-Ph-5 and C60, and CTOC-Ph-5F; and

FIG. 15b depicts corresponding enlarged views of the framed portions of the respective spectrum of FIG. 15a.

### DETAILED DESCRIPTION OF THE EMBODIMENTS

The present invention provides effective and facile methods to synthesize various CTOC-based cluster materials with different kinds of functional groups. The synthesis starts with the known CTOC and can be readily conducted with well-developed post-modification approaches, including post-synthetic ligand exchange and ligand derivatization reactions, in high yield. These methods can be conducted in a controllable manner to realize the functionalization of CTOC with varied ratios of the groups. The ligand exchange has been implemented by using the hierarchical activity of the surface ligands, while the derivatization was realized by thiol-ene/thiol-yne click reactions or radical polymerization of vinyl groups.

In particular, the present invention provides a cyclic titanium-oxide cluster (CTOC)-based composition of Formula I:

Ti₃₂O₁₆(OCH₂CH₂O)₃₂(R1COO)ₓ(ArCOO)₁₆₋ₓ(R2O)₁₆ (Formula I)
wherein:
x is an integer from 0 to 15,
R1 is selected from a group consisting of H—, CH₃—, CH₃CH₂—, CH₃CH₂CH₂—, (CH₃)₂CH—, (CH₃)₂CHCH₂—, (CH₃)₃C—, CH₂CH—, CH₂C(CH₃)—, CNCH₂—, CNCH₂CH₂—, HSCH₂—, HSCH₂CH₂—, NH₂CH₂—, NH₂CH₂CH₂—, OHCH₂—, OHCH₂CH₂—, CH₃NHCH₂— and (CH₃)₂NCH₂,
Ar is selected from a group consisting of o/m/p-CH₂CHPh—, o/m/p-CHCPh—, o/m/p-OHPh—, o/m/p-CH₃NHPh—, o/m/p-(CH₃)₂NPh—, o/m/p-SHPh—, o/m/p-CH₃SPh—, o/m/p-CH₃CH₂SPh—, o/m/p-F—Ph—, o/m/p-Cl—Ph—, o/m/p-Br—Ph—, o/m/p-I—Ph—, o/m/p-CF₃—Ph—, o/m/p-NH₂CH₂Ph—, o/m/p-(NH₃⁺X⁻)Ph—, o/m/p-(CH₃NH₂⁺X⁻)Ph—, o/m/p-[(CH₃)₃N⁺X⁻]Ph—, o/m/p-(NH₃⁺X⁻)CH₂Ph—, o/m/p-NH₂CH₂CH₂Ph— and o/m/p-(NH₃⁺X⁻)CH₂CH₂Ph—,

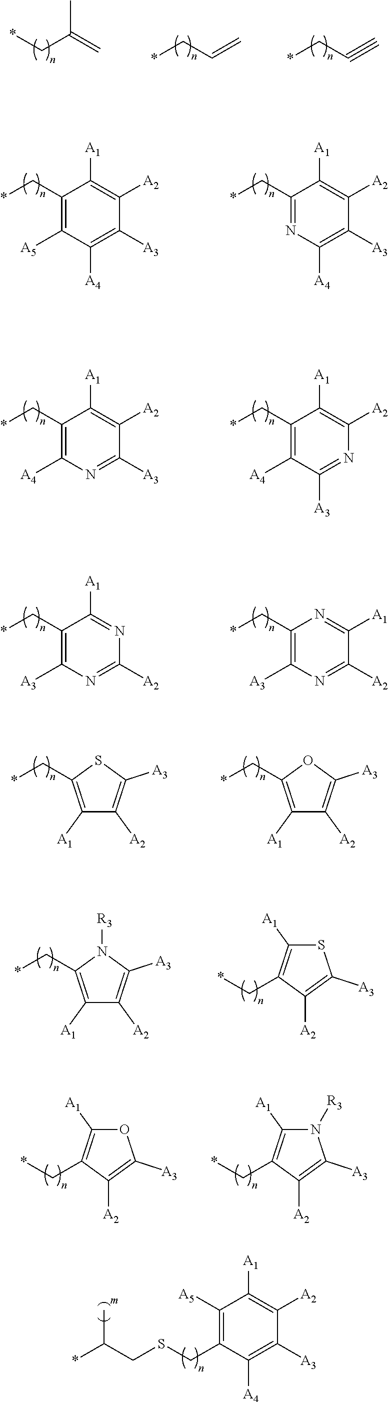

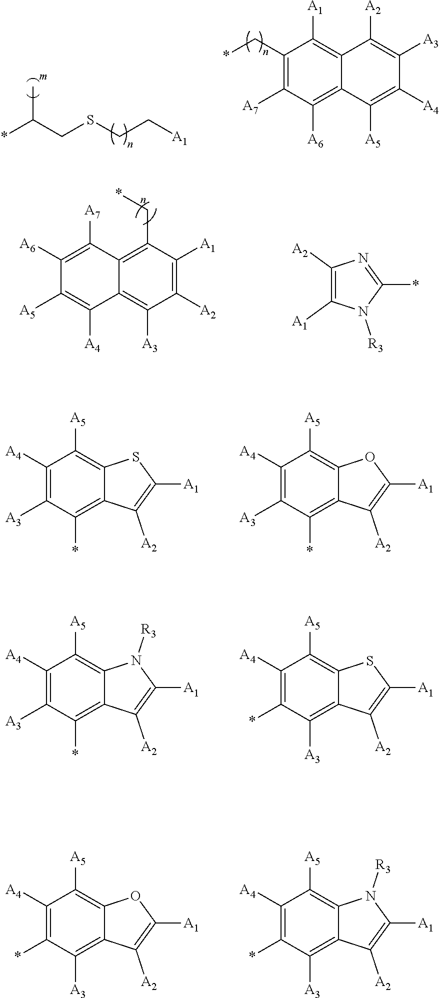

R2 is selected from a group consisting of CH₃—, CH₃CH₂—, CH₃CH₂CH₂—, (CH₃)₂CH—, CH₃CH₂CH₂CH₂—, OHCH₂CH₂—, OHCH₂CH₂CH₂—, SHCH₂CH₂—, SHCH₂CH₂CH₂—, NH₂CH₂CH₂—, NH₂CH₂CH₂CH₂—, CH₃NHCH₂CH₂—, (CH₃)₂NCH₂CH₂—, (NH₃⁺X⁻)CH₂CH₂—, (NH₃⁺X⁻)CH₂CH₂CH₂—, CH₃(NH₂⁺X⁻)CH₂CH₂—, (CH₃)₂(NH⁺X⁻)CH₂CH₂—,
X⁻ is selected from a group consisting of Cl⁻, Br⁻, I⁻, triflate (OTf⁻), BF₄⁻ and PF₆⁻,
each of A₁, A₂, A₃, A₄, A₅, A₆, A₇ is independently selected from a group consisting of: H, F, Cl, Br, I, CF₃,

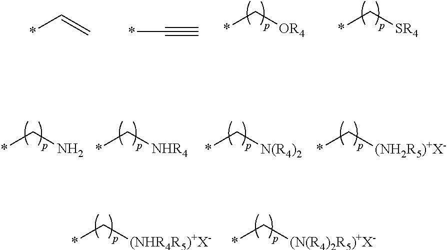

each of R₃, R₄, R₅ is further independently selected from a group consisting of:

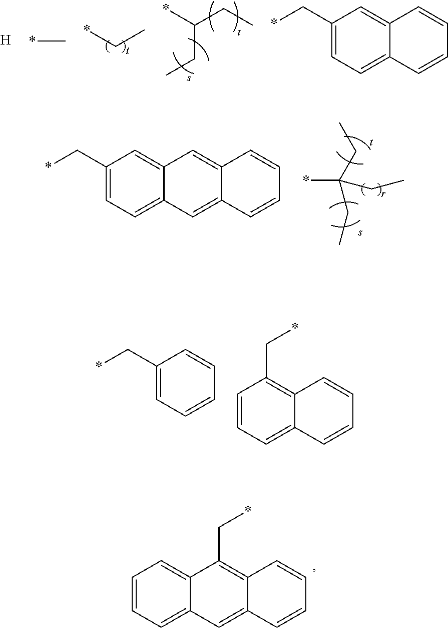

and
each of m, n, p, r, s and t is independently selected from an integer from 0 to 10.

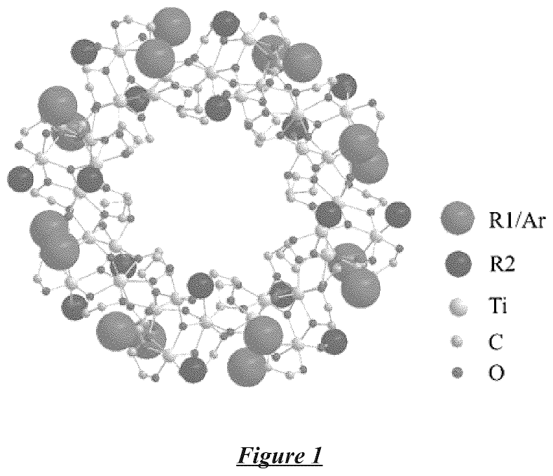

“o/m/p-” above stands for “ortho/meta/para-”. The expression “from . . . to . . . ” used in the preceding paragraph means that both integers are included. The general molecular structure of the CTOC-based nanocluster composition according to Formula I is shown in FIG. 1. It can be seen that the CTOC-based nanocluster composition has a general structure of a robust Ti₃₂O₁₆(OCH₂CH₂O)₃₂ core and variable surface groups. For clarify purpose, H atoms are not shown in FIG. 1.

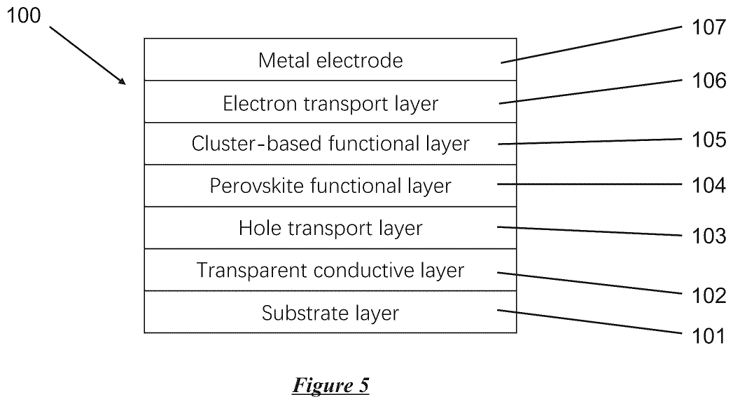

The present invention also provides a device containing the CTOC-based nanocluster composition according to the present invention. In certain embodiments, and as shown in FIG. 5, a device 100 (such as a perovskite solar cell) including CTOC-based nanocluster composition according to the present invention includes a substrate layer 101, a transparent conductive layer 102, a hole-transport layer 103, a perovskite functional layer 104 (which is fabricated with the nanocluster composition of the present application), a cluster-based functional layer 105, an electron-transport layer 106, and a metal electrode 107.

The substrate layer 101 is a flexible or rigid material with light transmittance greater than 80% (at 550 nm), and includes one or more of glass, polymethyl methacrylate (PMMA), polycarbonate (PC), purpose polystyrene (PS), polyethylene glycol terephthalate (PET), polyethylene naphthalate (PEN), polydimethylsiloxane (PDMS), styrene-ethylene-butylene-styrene (SEBS), ethylene terephthalateco-1,4-cylclohexylenedimethylene terephthalate (PETG), acrylonitrile butadiene styrene copolymers (ABS), polypropylene (PP), polyamide (PA) and acrylonitrile-styrene copolymer (AS).

The transparent conductive layer 102 includes one or more of indium tin oxide (ITO), aluminum zinc oxide (AZO), fluorine tin oxide (FTO), graphene, poly(3,4-ethylenedioxythiophene) polystyrene sulfonate (PEDOT:PSS), Ag nanowire, Cu nanowire.

The hole-transport layer 103 includes made of one or more of self-assembled monolayer, poly triaryl amine (PTAA), PEDOT:PSS, NiOₓ, 2,2′,7,7′-Tetrakis[N,N-di(4-methoxyphenyl)amino]-9,9′-spirobifluorene (Spiro-OMeTAD).

The perovskite functional layer 104 includes perovskite crystal grains. The perovskite crystal grain has an [A⁺¹B⁺²X⁻¹₃] structure, in which the A-site ion is one or more of formamidinium ion (FA⁺), methylammonium ion (MA⁺), Cs⁺, Rb⁺, ethylammonium ion (EA⁺), guanidinium ion (GA⁺), the B-site ion is Pb²⁺ or a compound of Pb²⁺ and other metals (such as Sn²⁺ or Ge²⁺), and X-site is one or more of I⁻, Br⁻ and Cl⁻.

The cluster-based functional layer 105 is formed (at least primarily) of one or more CTOC-based cluster materials according to the present invention.

The electron-transport layer 106 includes one or more of [6,6]-phenyl-C₆₁-butyric acid methyl ester (PC₆₁BM), buckminsterfullerene (C60), SnO₂, and TiO₂.

The metal electrode 107 is vapor-deposited on the surface of the device 100 by a metal material with resistivity less than 5×10⁻⁷ Ω·m (at 25° C.). The metal material is one or more of Ag, Cu, Au, Al, W, Fe and Pt.

In certain embodiments, in a method of manufacturing a device 100 (such as a perovskite solar cell) of a p-i-in structure, the substrate layer 101 deposited with the transparent conductive layer 102 (5-70 Ω sq⁻¹) were sequentially cleaned by sonication with detergent, deionized water, acetone, and isopropyl alcohol for 15-90 minutes, respectively. Then, the combined substrates 101, 102 were dried at 40-125° C. in an oven for over 1 hour. The cleaned and dry substrates 101, 102 were treated with oxygen plasma for 10-75 minutes and then transferred into an N2-filled glovebox before use. A hole-transport solution was spin-coated onto the transparent conductive layer 102 at 1,000-10,000 rpm for 5-90 seconds and the substrates were subsequently annealed at 75-180° C. for 5-90 minutes to form the hole-transport layer 103. Perovskite solutions were spin-coated onto the hole-transport layer 103 at 300-12,000 rpm for 10-140 seconds. Antisolvent was slowly dripped onto the center of the film at 3-35 seconds before the end of spin-coating. The as-prepared perovskite films were subsequently transferred to a hotplate at 65-180° C. for 6-120 minutes. The spin-coating processes were all conducted when the substrates and films were cooled down at room temperature. Finally, the electron-transport layer 105 and metal electrode 106 were thermally evaporated under high vacuum (<5×10⁻⁶ Torr).

In certain embodiments, in a method of manufacturing a device 100 (such as a perovskite solar cell) of a n-i-p structure, the substrate layer 101 deposited with a transparent conductive layer 102 (5-70 Ω sq⁻¹) were sequentially cleaned by sonication with detergent, deionized water, acetone, and isopropyl alcohol for 15-90 minutes, respectively. Then, the combined substrates 101, 102 were dried at 40-125° C. in an oven for over 1 hour. The cleaned and dry substrates 101, 102 were treated with oxygen plasma for 10-75 minutes and then transferred into an N2-filled glovebox before use. Electron-transport layer solution was spin-coated onto the transparent conductive layer 102 at 1,000˜10,000 rpm for 5-90 seconds and the substrates were subsequently annealed at 100-500° C. for 10-100 minutes. Perovskite solutions were spin-coated onto an electron-transport layer 106 at 300-12,000 rpm for 10-140 seconds. Antisolvent was slowly dripped onto the center of the film at 3-35 seconds before the end of spin-coating. The as-prepared perovskite films were subsequently transferred to a hotplate at 65-180° C. for 6-120 minutes. The spin-coating processes were all conducted when the substrates and films were cooled down at room temperature. Then, the hole-transport layer 103 was spin-coated onto the perovskite layer 104 at 300-12,000 rpm for 10-140 seconds. Finally, metal electrodes 106 were thermally evaporated under a high vacuum (<5×10⁻⁶ Torr).

In certain embodiments, the organic-inorganic hybrid perovskite has a chemical formula of Cs_{0.01-0.5}MA_{0.01-0.5}FA_{0.01-0.5}PbI₃. 1.0-2.5 M perovskite precursor solutions were constructed by mixing FAI, PbI₂, MAI, and CsI powders in 1 mL dimethylformamide:dimethyl sulfoxide (DMF:DMSO) mixed solvent (4:1/v:v). 1-10 mol % excessive PbI₂ and 1-40 mol % MACl were added into the precursor solution. For target perovskite with mercaptonicotinic acid (MNAs), the solution of MNAs or solid powder was added to the precursor solution directly with a final molarity of 0.01-0.5 M. The prepared precursor solution can be mixed with a vortex mixer before use.

In certain embodiments, the CTOC is introduced into the device 100 as follows. In a p-i-n structured device 100, the CTOC powder or solution was dissolved in solvents (such as chloroform and chlorobenzene with a concentration of 0.5-10 mg/mL), and then directly spin-coated onto the perovskite film 104 surface. To dry out the solvent, the film was annealed at 60-100° C. for 2-20 minutes. Then the device 100 was moved for evaporation of the electron-transport layer 106 and the metal electrode 107.

In an n-i-p structured device 100, the CTOC powder or solution was dissolved in solvents (such as chloroform and chlorobenzene with a concentration of 0.5-10 mg/mL), and then directly spin-coated onto the electron-transport layer 106. To dry out the solvent, the film was annealed at 60-100° C. for 2-20 minutes. Then the substrate was transferred into an N2-filled glovebox before use.

In certain embodiments, the rigid/flexible perovskite solar modules fabrication is as follows. The perovskite precursor solution was meniscus-coated on the substrate layer 101/transparent conductive layer 102/hole-transport layer 103. Next, the substrates coated with perovskite precursor were heat-annealed at 75˜200° C. for 5-120 minutes on a hotplate. Then electron-transport materials was dissolved in anhydrous chlorobenzene to form the electron-transport layer 105. Finally, the metal electrode 107 was deposited by vacuum evaporation under high vacuum (<5×10⁻⁶ Torr).

For CTOC-Ph-5F bearing eight pentafluorobenzene groups of Formula II:

Ti₃₂O₁₆(OCH₂CH₂O)₃₂[(CH₃)₃CCOO]₈(C₆F₅COO)₈(CH₃CH₂O)₁₆ (Formula II)

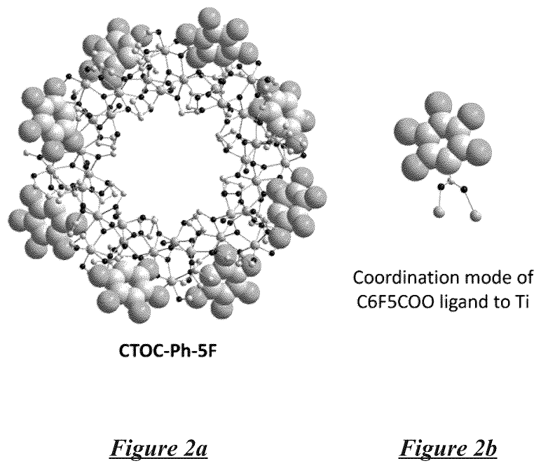

the typical synthesis can be conducted by dissolving bare CTOC (50 mg) and pentafluorobenzene acid (30 mg) in mixed solvents of dichloromethane (2 mL) and ethanol (2 mL) in a vial with addition of triethylamine (20 μL) to adjust the acidity of the mixture. The mixture was then sealed and incubated in an oven at 30° C. to 50° C. for 3 days. After cooling down completely, the mixture was concentrated by a rotary evaporator to 1 mL and colorless crystalline was observed. The white powder of the product was finally obtained by centrifugation washed with fresh ethanol three times and dried in the vacuum oven. The yield could be 50% or higher based on CTOC. Crystals of CTOC-Ph-5F suitable for single crystallography analysis could be obtained when the mixture is incubated in the oven for seven days. The single crystal structure is shown in FIGS. 2a and 2b.

When p-fluorobenzene acid or p-trifluoromethyl benzene acid in place of pentafluorobenzene acid, CTOC-Ph-F of Formula IV:

Ti₃₂O₁₆(OCH₂CH₂O)₃₂[(CH₃)₃CCOO]₈(C₆H₄FCOO)₈(CH₃CH₂O)₁₆ (Formula IV)

### and CTOC-Ph-CF3 of Formula III:

Ti₃₂O₁₆(OCH₂CH₂O)₃₂[(CH₃)₃CCOO]₈(p-CF₃PhCOO)₈(CH₃CH₂O)₁₆ (Formula III)

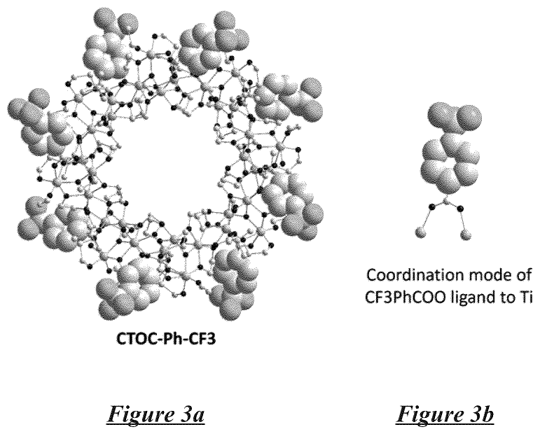

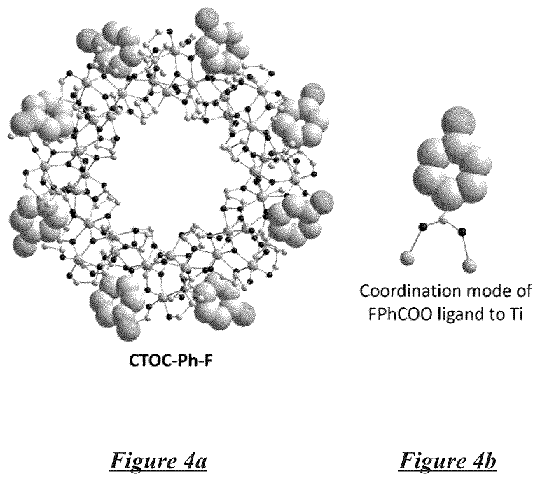

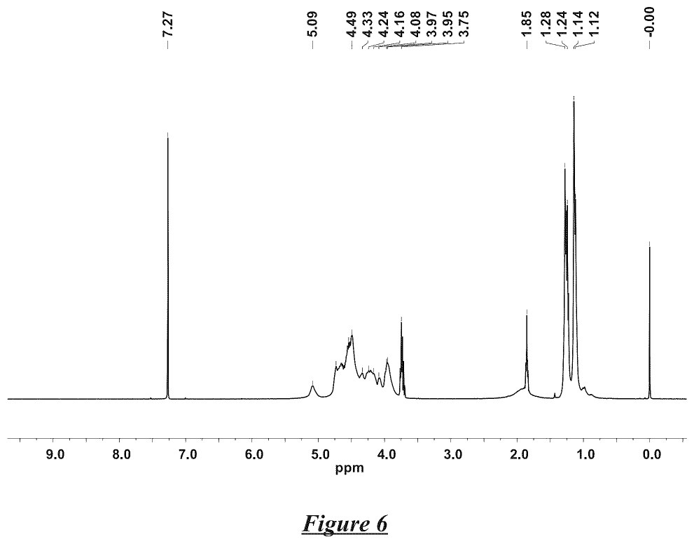

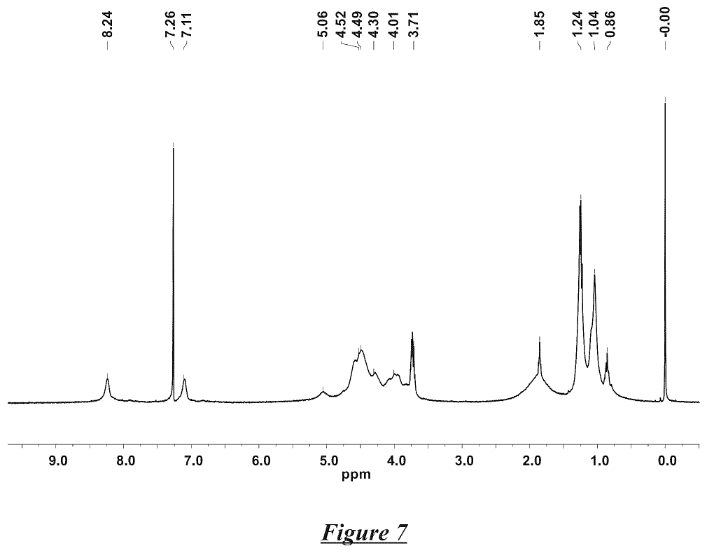

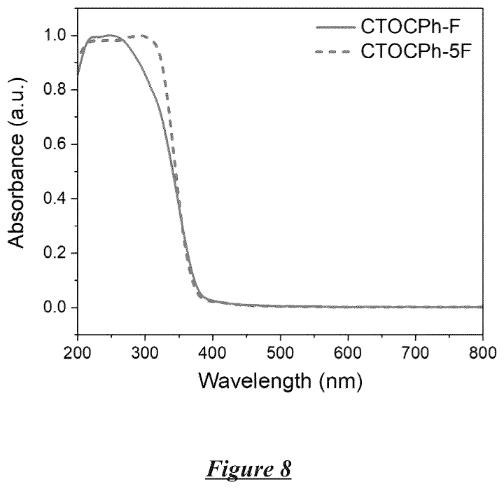

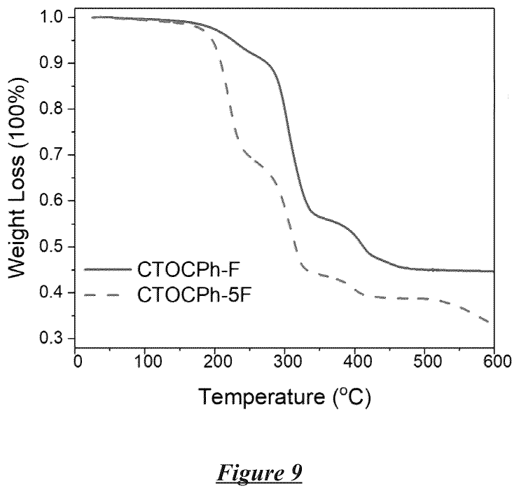

could be formed instead. The respective single crystal structures are shown in FIGS. 4a and 4b and FIGS. 3a and 3b respectively. Besides the single crystal structures, FIG. 6 and FIG. 7 showing the respective ¹H NMR spectrum of CTOC-Ph-5F and CTOC-Ph-F further prove their respective compositions. Besides, their respective UV-vis and TGA spectra are also shown in FIG. 8 and FIG. 9.

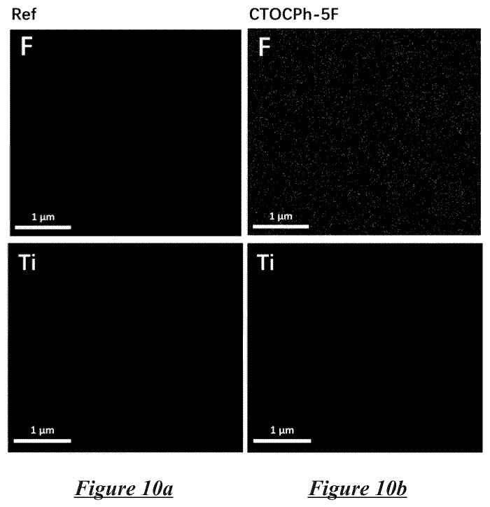

The derived CTOC-based functionalized nanoclusters can be well soluble in chloroform, dichloromethane, etc. with high concentration. By spin-coating their solution with different concentrations, smooth and uniform films with varied thicknesses can be formed. In the embodiment of FIGS. 10a and 10b, the EDX mapping of F and Ti shows an even distribution of the CTOC-Ph-5F on the perovskite film surface 104.

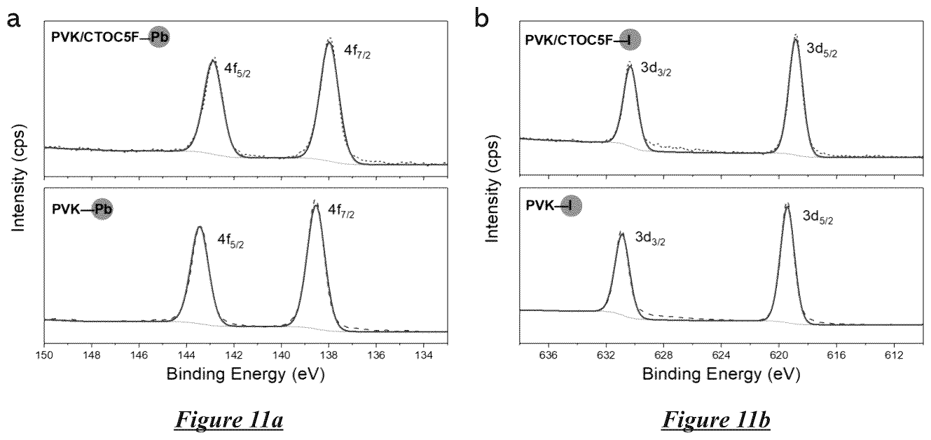

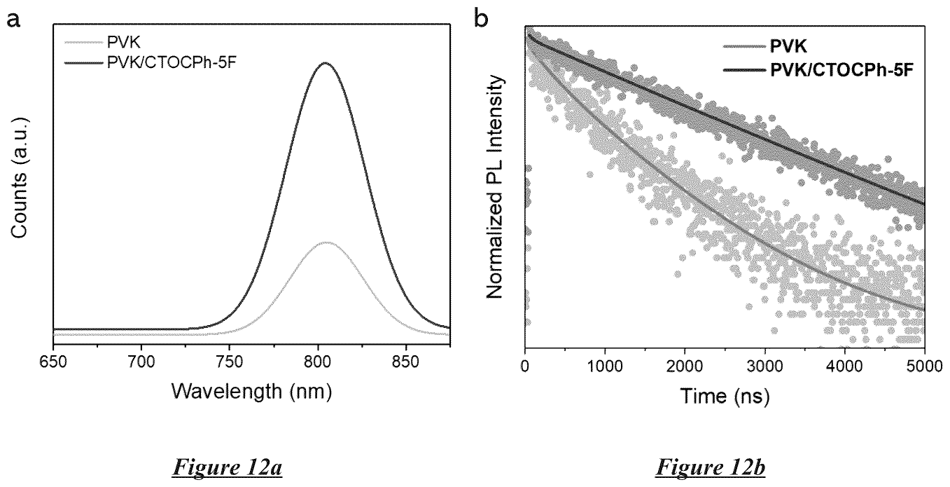

The interaction between CTOC-Ph-5F and perovskite can be first characterized by X-ray photoelectron spectroscopy (XPS). As shown in FIGS. 11a and 11b, the binding energy of Pb and I shift about 57 meV, indicating the increased electron density with CTOC-Ph-5F coating. Also, as shown in FIGS. 12a and 12b, the increased PL intensity and prolonged PL lifetime further demonstrate the defects passivation and reduced non-radiative recombination.

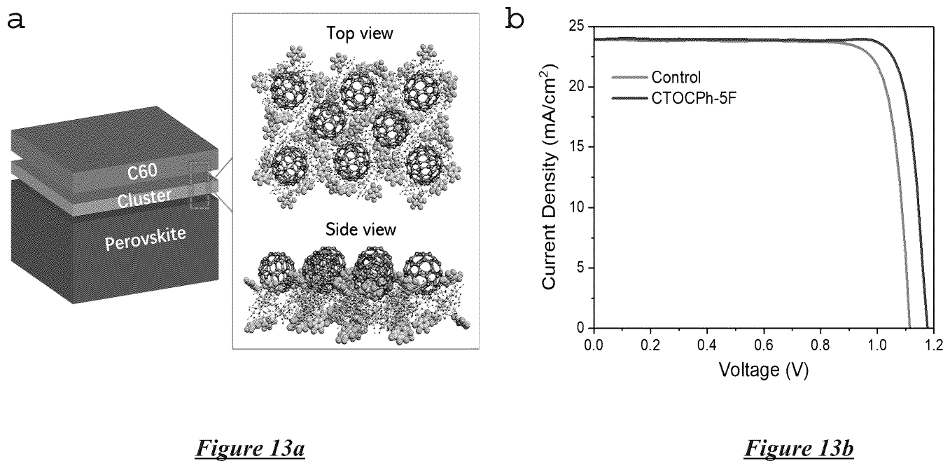

P-i-n structured PVSCs were fabricated to evaluate the photovoltaic performance based on CTOC-coated perovskite films. As shown in FIGS. 13a and 13b, the highest PCE of the control device is 21.94%, with a V_{OC} of 1.11 V, J_{SC} of 23.91 mA/cm² and FF of 82.67%. However, the champion PCE of the CTOC-coated device is significantly improved to 23.98% (V_{OC} of 1.19 V, J_{SC} of 23.94 mA/cm², FF of 84.89%). Note that with the coating of an anti-reflection layer, the Jsc can be increased to about 25.5 mA/cm², due to the enhanced light absorption. And the champion PCE can be boosted to over 25%.

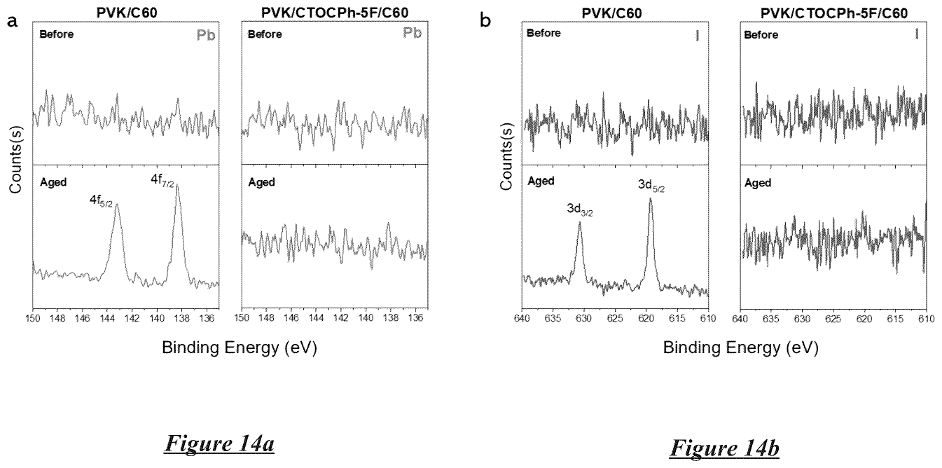

To evaluate the stability of perovskite film with a CTOC coating layer, the perovskite film with or without CTOC was evaporated with C60 and aged under 85° C. for about 150 hours. FIGS. 14a and 14b show that the control film has decomposed as the XPS peaks of Pb and I appeared. The CTOC coating layer shows no XPS peaks of Pb and I, demonstrating the highly enhanced film stability with the CTOC coating layer.

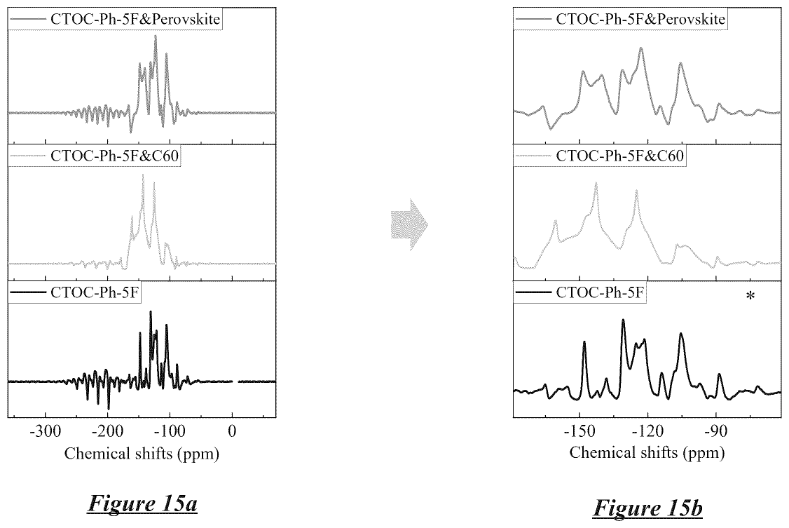

The CTOC-based compositions of the present invention enhance the intermocular interaction and electronic communication of the functional layer with the pervoskite layer and the electronic-transport layer (which is made of C60/fullerene). For example, the pentafluorophenyl (C₆F₅) group can effectively interact with not only Pb but also C60. FIG. 15a depicts, from bottom to top, the respective solid fluorine-19 nuclear magnetic resonance (NMR ¹⁹F) spectrum of CTOC-Ph-5F, CTOC-Ph-5 and C60, and CTOC-Ph-5F and perovskite, and FIG. 15b depicts corresponding enlarged views of the framed portions of the respective spectrum of FIG. 15a.

Referring firstly to the solid NMR ¹⁹F spectrum of CTOC-Ph-5F

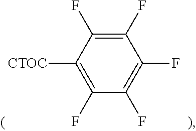

because the rotation of the C₆F₅ ring is restrained in solid as revealed by the single crystal structure, the signal of F in CTOC-Ph-5F can be assigned by five signals of −105.4, −121.6, −125.2, −130.9 and −148.1 ppm, respectively. As for the solid NMR ¹⁹F spectrum of CTOC-Ph-5 and C60, the signals can be shifted and broadened to −103.6, −124.9, −142.9, −154.1 and −160.6 ppm. Turning to the solid NMR ¹⁹F spectrum of CTOC-Ph-5F and perovskite, the signals can be shifted to −105.7, −122.8, −131.2, −140.3 and −148.6 ppm. The variations of the chemical shifts can be attributed to the intermocular interactions.

It should be understood that the above only illustrates examples whereby the present invention may be carried out, and that various modifications and/or alterations may be made thereto without departing from the spirit of the invention.

It should also be understood that certain features of the invention, which are, for clarity, described in the context of separate embodiments, may be provided in combination in a single embodiment. Conversely, various features of the invention which are, for brevity, described in the context of a single embodiment, may also be provided separately or in any appropriate sub-combinations.

1. A cyclic titanium-oxide cluster (CTOC)-based composition of Formula I:
Ti₃₂O₁₆(OCH₂CH₂O)₃₂(R1COO)ₓ(ArCOO)₁₆₋ₓ(R2O)₁₆ (Formula I)
wherein:
x is an integer from 0 to 15,
R1 is selected from a group consisting of H—, CH₃—, CH₃CH₂—, CH₃CH₂CH₂—, (CH₃)₂CH—, (CH₃)₂CHCH₂—, (CH₃)₃C—, CH₂CH—, CH₂C(CH₃)—, CNCH₂—, CNCH₂CH₂—, HSCH₂—, HSCH₂CH₂—, NH₂CH₂—, NH₂CH₂CH₂—, OHCH₂—, OHCH₂CH₂—, CH₃NHCH₂— and (CH₃)₂NCH₂,
Ar is selected from a group consisting of o/m/p-CH₂CHPh—, o/m/p-CHCPh—, o/m/p-OHPh—, o/m/p-CH₃NHPh—, o/m/p-(CH₃)₂NPh—, o/m/p-SHPh—, o/m/p-CH₃SPh—, o/m/p-CH₃CH₂SPh—, o/m/p-F—Ph—, o/m/p-Cl—Ph—, o/m/p-Br—Ph—, o/m/p-I—Ph—, o/m/p-CF₃—Ph—, o/m/p-NH₂CH₂Ph—, o/m/p-(NH₃⁺X⁻)Ph—, o/m/p-(CH₃NH₂⁺X⁻)Ph—, o/m/p-[(CH₃)₃N⁺X⁻]Ph—, o/m/p-(NH₃⁺X⁻)CH₂Ph—, o/m/p-NH₂CH₂CH₂Ph— and o/m/p-(NH₃⁺X⁻)CH₂CH₂Ph—, 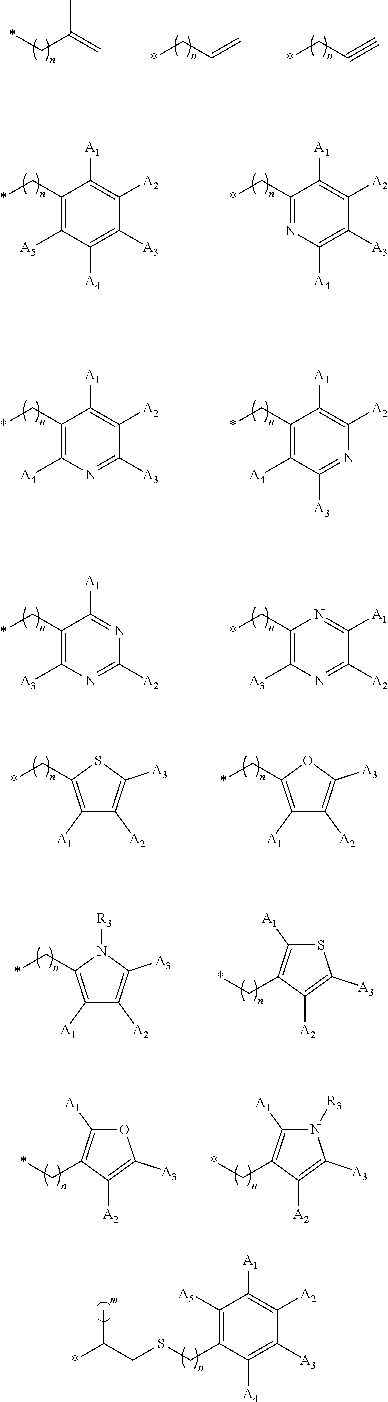 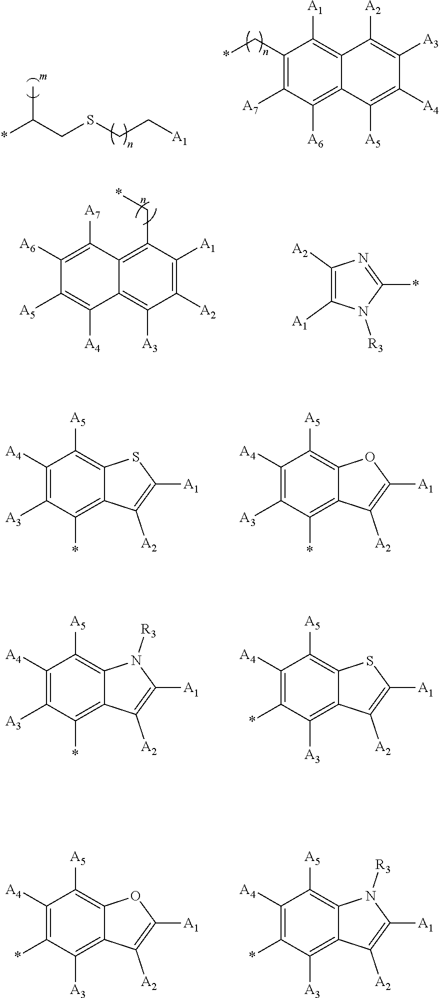
R2 is selected from a group consisting of CH₃—, CH₃CH₂—, CH₃CH₂CH₂—, (CH₃)₂CH—, CH₃CH₂CH₂CH₂—, OHCH₂CH₂—, OHCH₂CH₂CH₂—, SHCH₂CH₂—, SHCH₂CH₂CH₂—, NH₂CH₂CH₂—, NH₂CH₂CH₂CH₂—, CH₃NHCH₂CH₂—, (CH₃)₂NCH₂CH₂—, (NH₃⁺X⁻)CH₂CH₂—, (NH₃⁺X⁻)CH₂CH₂CH₂—, CH₃(NH₂⁺X⁻)CH₂CH₂—, (CH₃)₂(NH⁺X⁻)CH₂CH₂—,
X⁻ is selected from a group consisting of Cl⁻, Br⁻, I⁻, OTf⁻, BF₄⁻ and PF₆⁻,
each of A₁, A₂, A₃, A₄, A₅, A₆, A₇ is independently selected from a group consisting of: H, F, Cl, Br, I, CF₃, 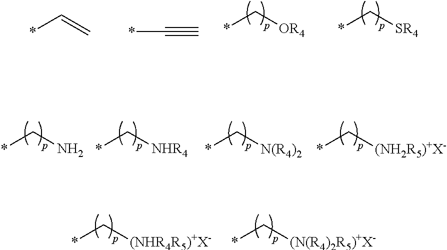
each of R₃, R₄, R₅ is independently selected from a group consisting of: 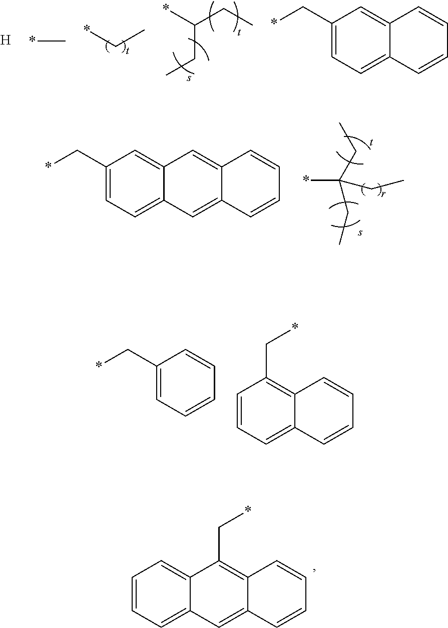
and
each of m, n, p, r, s and t is independently selected from an integer from 0 to 10.

2. The composition of claim 1, wherein the cyclic titanium-oxide cluster (CTOC)-based composition is:
Ti₃₂O₁₆(OCH₂CH₂O)₃₂[(CH₃)₃CCOO]₈(C₆F₅COO)₈(CH₃CH₂O)₁₆ (Formula II).

3. The composition of claim 1, wherein the cyclic titanium-oxide cluster (CTOC)-based composition is:
Ti₃₂O₁₆(OCH₂CH₂O)₃₂[(CH₃)₃CCOO]₈(p-CF₃PhCOO)₈(CH₃CH₂O)₁₆ (Formula III).

4. The composition of claim 1, wherein the cyclic titanium-oxide cluster (CTOC)-based composition is:
Ti₃₂O₁₆(OCH₂CH₂O)₃₂[(CH₃)₃CCOO]₈(C₆H₄FCOO)₈(CH₃CH₂O)₁₆ (Formula IV)

5. A device including a cyclic titanium-oxide cluster (CTOC)-based composition of Formula I:
Ti₃₂O₁₆(OCH₂CH₂O)₃₂(R1COO)ₓ(ArCOO)₁₆₋ₓ(R2O)₁₆ (Formula I)
wherein:
x is an integer from 0 to 15,
R1 is selected from a group consisting of H—, CH₃—, CH₃CH₂—, CH₃CH₂CH₂—, (CH₃)₂CH—, (CH₃)₂CHCH₂—, (CH₃)₃C—, CH₂CH—, CH₂C(CH₃)—, CNCH₂—, CNCH₂CH₂—, HSCH₂—, HSCH₂CH₂—, NH₂CH₂—, NH₂CH₂CH₂—, OHCH₂—, OHCH₂CH₂—, CH₃NHCH₂— and (CH₃)₂NCH₂,
Ar is selected from a group consisting of o/m/p-CH₂CHPh—, o/m/p-CHCPh—, o/m/p-OHPh—, o/m/p-CH₃NHPh—, o/m/p-(CH₃)₂NPh—, o/m/p-SHPh—, o/m/p-CH₃SPh—, o/m/p-CH₃CH₂SPh—, o/m/p-F—Ph—, o/m/p-Cl—Ph—, o/m/p-Br—Ph—, o/m/p-I—Ph—, o/m/p-CF₃—Ph—, o/m/p-NH₂CH₂Ph—, o/m/p-(NH₃⁺X⁻)Ph—, o/m/p-(CH₃NH₂⁺X⁻)Ph—, o/m/p-[(CH₃)₃N⁺X⁻]Ph—, o/m/p-(NH₃⁺X⁻)CH₂Ph—, o/m/p-NH₂CH₂CH₂Ph— and o/m/p-(NH₃⁺X⁻)CH₂CH₂Ph—, 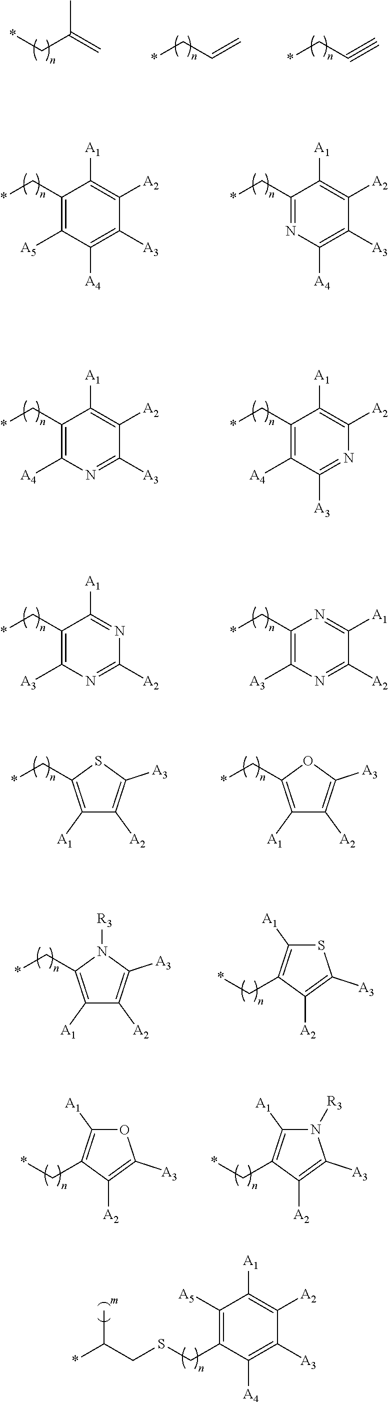 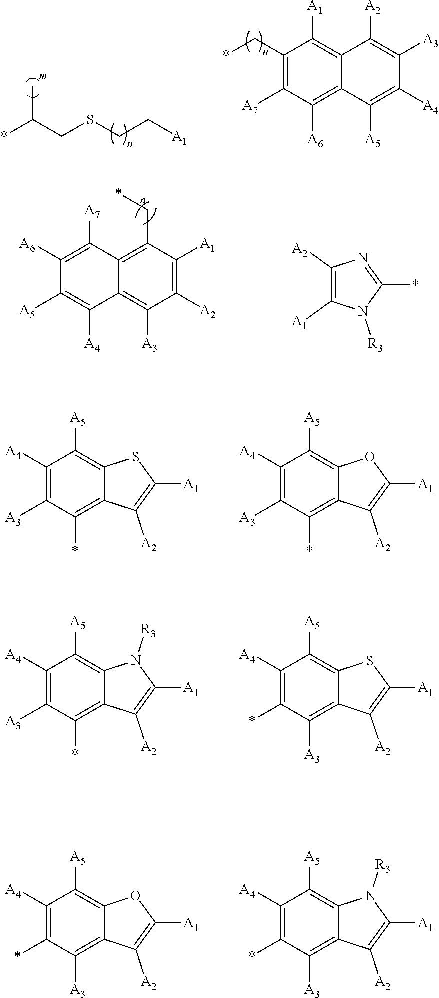
R2 is selected from a group consisting of CH₃—, CH₃CH₂—, CH₃CH₂CH₂—, (CH₃)₂CH—, CH₃CH₂CH₂CH₂—, OHCH₂CH₂—, OHCH₂CH₂CH₂—, SHCH₂CH₂—, SHCH₂CH₂CH₂—, NH₂CH₂CH₂—, NH₂CH₂CH₂CH₂—, CH₃NHCH₂CH₂—, (CH₃)₂NCH₂CH₂—, (NH₃⁺X⁻)CH₂CH₂—, (NH₃⁺X⁻)CH₂CH₂CH₂—, CH₃(NH₂⁺X⁻)CH₂CH₂—, (CH₃)₂(NH⁺X⁻)CH₂CH₂—,
X⁻ is selected from a group consisting of Cl⁻, Br⁻, I⁻, OTf⁻, BF₄⁻ and PF₆⁻,
each of A₁, A₂, A₃, A₄, A₅, A₆, A₇ is independently selected from a group consisting of: H, F, Cl, Br, I, CF₃, 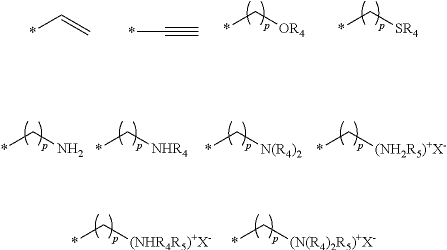
each of R₃, R₄, R₅ is independently selected from a group consisting of: 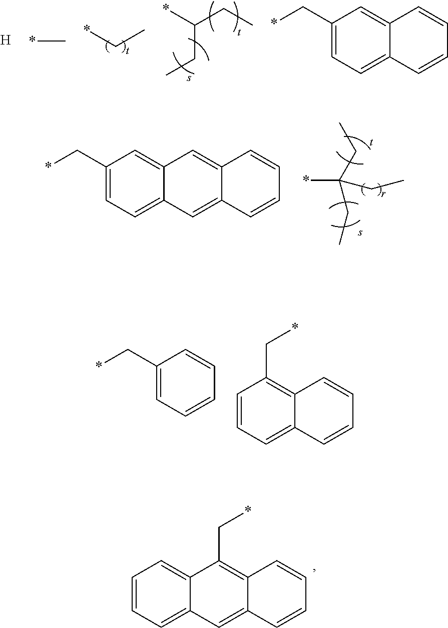
and each of m, n, p, r, s and t is independently selected from an integer from 0 to 10.

6. The device of claim 5, wherein said device includes a perovskite functional layer coated with the cyclic titanium-oxide cluster (CTOC)-based composition.

7. The device of claim 6, further including a substrate layer, a transparent conductive layer, a hole-transparent layer, an electron-transport layer and a metal electrode.

8. The device of claim 5, wherein said device comprises a perovskite solar cell.

9. A method of forming a device,
wherein said device includes a perovskite layer, and
wherein a layer of a cyclic titanium-oxide cluster (CTOC)-based composition is formed on said perovskite layer, the cyclic titianium-oxide cluster (CTOC)-based composition comprising:
Ti₃₂O₁₆(OCH₂CH₂O)₃₂(R1COO)ₓ(ArCOO)₁₆₋ₓ(R2O)₁₆ (Formula I)
wherein:
x is an integer from 0 to 15,
R1 is selected from a group consisting of H—, CH₃—, CH₃CH₂—, CH₃CH₂CH₂—, (CH₃)₂CH—, (CH₃)₂CHCH₂—, (CH₃)₃C—, CH₂CH—, CH₂C(CH₃)—, CNCH₂—, CNCH₂CH₂—, HSCH₂—, HSCH₂CH₂—, NH₂CH₂—, NH₂CH₂CH₂—, OHCH₂—, OHCH₂CH₂—, CH₃NHCH₂— and (CH₃)₂NCH₂,
Ar is selected from a group consisting of o/m/p-CH₂CHPh—, o/m/p-CHCPh—, o/m/p-OHPh—, o/m/p-CH₃NHPh—, o/m/p-(CH₃)₂NPh—, o/m/p-SHPh—, o/m/p-CH₃SPh—, o/m/p-CH₃CH₂SPh—, o/m/p-F—Ph—, o/m/p-Cl—Ph—, o/m/p-Br—Ph—, o/m/p-I—Ph—, o/m/p-CF₃—Ph—, o/m/p-NH₂CH₂Ph—, o/m/p-(NH₃⁺X⁻)Ph—, o/m/p-(CH₃NH₂⁺X⁻)Ph—, o/m/p-[(CH₃)₃N⁺X⁻]Ph—, o/m/p-(NH₃⁺X⁻)CH₂Ph—, o/m/p-NH₂CH₂CH₂Ph— and o/m/p-(NH₃⁺X⁻)CH₂CH₂Ph—, 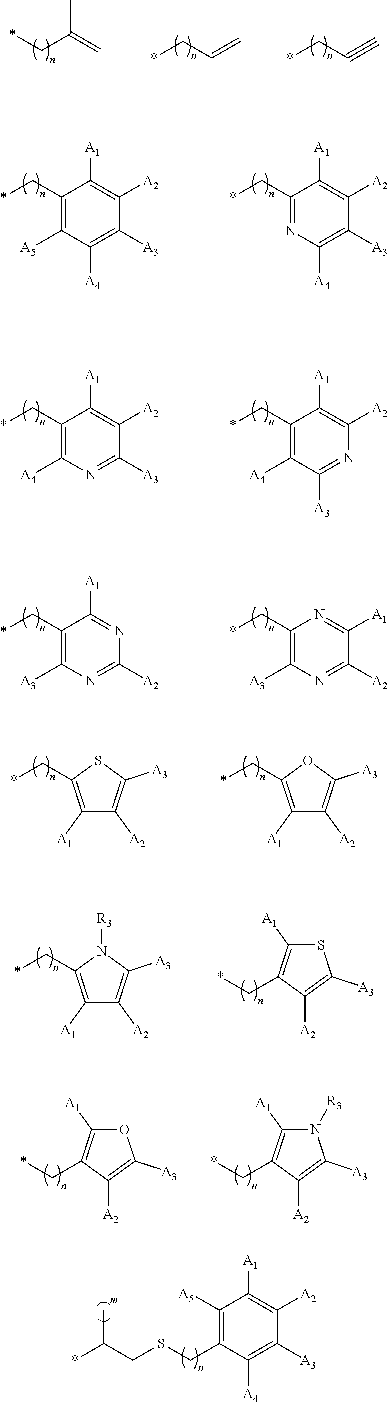 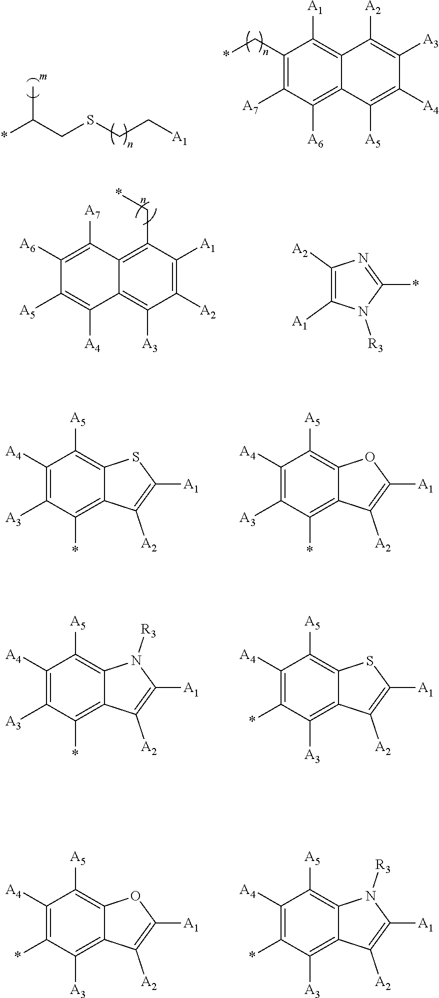
R2 is selected from a group consisting of CH₃—, CH₃CH₂—, CH₃CH₂CH₂—, (CH₃)₂CH—, CH₃CH₂CH₂CH₂—, OHCH₂CH₂—, OHCH₂CH₂CH₂—, SHCH₂CH₂—, SHCH₂CH₂CH₂—, NH₂CH₂CH₂—, NH₂CH₂CH₂CH₂—, CH₃NHCH₂CH₂—, (CH₃)₂NCH₂CH₂—, (NH₃⁺X⁻)CH₂CH₂—, (NH₃⁺X⁻)CH₂CH₂CH₂—, CH₃(NH₂⁺X⁻)CH₂CH₂—, (CH₃)₂(NH⁺X⁻)CH₂CH₂—,
X⁻ is selected from a group consisting of Cl⁻, Br⁻, I⁻, OTf⁻, BF₄⁻ and PF₆⁻,
each of A₁, A₂, A₃, A₄, A₅, A₆, A₇ is independently selected from a group consisting of: H, F, Cl, Br, I, CF₃, 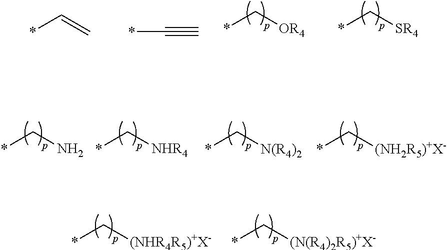
each of R₃, R₄, R₅ is independently selected from a group consisting of: 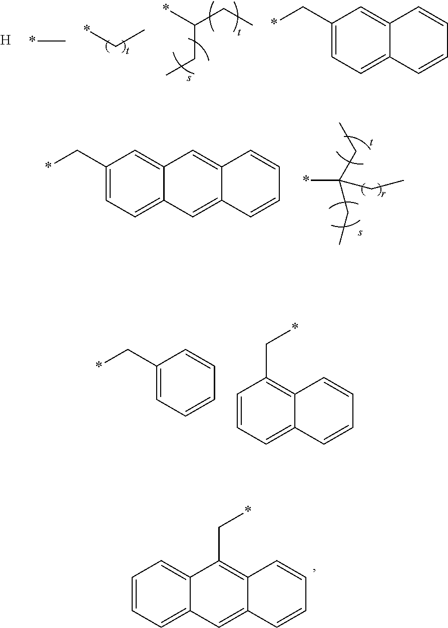
and
each of m, n, p, r, s and t is independently selected from an integer from 0 to 10.

10. The method of claim 9, further including spin-coating perovskite solutions onto an electron-transport layer to form said perovskite layer.

11. The method of claim 10, further including:
dissolving the cyclic titanium-oxide cluster (CTOC)-based composition in a solvent to form a dissolved composition,
spin-coating said dissolved composition onto said perovskite layer.

12. The method of claim 9, further including:
dissolving the cyclic titanium-oxide cluster (CTOC)-based composition in a solvent to form a dissolved composition, and
spin-coating said dissolved composition onto an electron-transport layer.
